(19) United States
(12) Patent Application Publication
(10) Pub. No.: US 2018/0175109 A1
(43) Pub. Date: Jun. 21, 2018

(54) VARIABLE RESISTANCE MEMORY DEVICE

(71) Applicant: SAMSUNG ELECTRONICS CO., LTD., Suwon-si (KR)

(72) Inventors: Hye-jin CHOI, Bucheon-si (KR); Jung-ik OH, Hwaseong-si (KR); Bok-yeon WON, Yongin-si (KR); Gwang-hyun BAEK, Seoul (KR)

(21) Appl. No.: 15/796,919

(22) Filed: Oct. 30, 2017

(30) Foreign Application Priority Data
Dec. 15, 2016 (KR) 10-2016-0171667

(51) Int. Cl. H01L 27/24; H01L 45/00; G11C 13/00

(52) U.S. Cl. CPC H01L 27/2463; G11C 2213/32; H01L 45/1246; H01L 27/2427; H01L 45/126; G11C 13/0069; H01L 27/2418; H01L 45/06; H01L 45/08; G11C 13/0004; G11C 13/0007; G11C 2213/15; G11C 2213/72; H01L 45/142; H01L 45/143; H01L 45/144; H01L 45/146; G11C 2213/52; H01L 45/1233

(57) ABSTRACT

A variable resistance memory device including a first electrode line; a cell structure including a variable resistance layer on the first electrode line and a first blocking layer protecting the variable resistance layer; and a second electrode line on the cell structure, wherein the first blocking layer is on at least one of an upper surface, a lower surface, and the upper and lower surfaces of the variable resistance layer, and the first blocking layer includes a metal layer or a carbon-containing conductive layer.

### CROSS-REFERENCE TO RELATED APPLICATION

Korean Patent Application No. 10-2016-0171667, filed on Dec. 15, 2016, in the Korean Intellectual Property Office, and entitled: “Variable Resistance Memory Device,” is incorporated by reference herein in its entirety.

### BACKGROUND

### 1. Field

Embodiments relate to a variable resistance memory device.

### 2. Description of the Related Art

Variable resistance memory devices, which utilize the current transfer properties of a variable resistance layer according to an applied voltage, have attracted attention as a replacement of flash memory devices. Examples of the variable resistance memory device may include phase change random access memory (PRAM) or resistive RAM (RRAM).

### SUMMARY

The embodiments may be realized by providing a variable resistance memory device including a first electrode line; a cell structure including a variable resistance layer on the first electrode line and a first blocking layer protecting the variable resistance layer; and a second electrode line on the cell structure, wherein the first blocking layer is on at least one of an upper surface, a lower surface, and the upper and lower surfaces of the variable resistance layer, and the first blocking layer includes a metal layer or a carbon-containing conductive layer.

The embodiments may be realized by providing a variable resistance memory device including a plurality of first electrode lines extending in a first direction and arranged in parallel and spaced apart from each other; a plurality of second electrode lines extending in a second direction perpendicular to the first direction, above the plurality of first electrode lines, and arranged in parallel and spaced apart from each other; and a plurality of memory cells at intersections of the plurality of first electrode lines and the plurality of second electrode lines and spaced apart from each other, wherein: each of the plurality of memory cells includes a cell structure that is electrically connected to one of first electrode lines and one of second electrode lines, and includes a selection device layer, an intermediate electrode layer, a variable resistance layer, and a blocking layer, the blocking layer is on at least one of an upper surface, a lower surface, and the upper and lower surfaces of the selection device layer or the variable resistance layer, and the blocking layer includes a metal layer or a carbon-containing conductive layer.

The embodiments may be realized by providing a variable resistance memory device including a first electrode line layer on a substrate, the first electrode line layer including a plurality of first electrode lines arranged in parallel and spaced apart from each other in a first direction; a second electrode line layer arranged above the first electrode line layer and including a plurality of second electrode lines arranged in parallel and spaced apart from each other in a second direction perpendicular to the first direction; a third electrode line layer arranged above the second electrode line layer and including a plurality of third electrode lines arranged identically corresponding to the plurality of first electrode lines; a first memory cell layer including a plurality of first memory cells arranged at intersections of the plurality of first electrode lines and the plurality of second electrode lines; and a second memory cell layer including a plurality of second memory cells arranged at intersections of the plurality of second electrode lines and the plurality of third electrode lines, wherein: each of the plurality of first memory cells and the plurality of second memory cells includes a cell structure including a selection device layer, an intermediate electrode layer, a variable resistance layer, and a blocking layer, and the blocking layer is formed on at least one of an upper surface, a lower surface, and the upper and lower surfaces of each of the selection device layer and the variable resistance layer, and the blocking layer includes a metal layer or a carbon-containing conductive layer.

The embodiments may be realized by providing a variable resistance memory device including a first electrode line; a second electrode line; and a cell structure between the first electrode line and the second electrode line, the cell structure including a variable resistance layer on the first electrode line and a first blocking layer protecting the variable resistance layer, wherein: the first blocking layer directly contacts at least one surface of the variable resistance layer, and the first blocking layer includes a metal layer or a carbon-containing conductive layer.

### BRIEF DESCRIPTION OF THE DRAWINGS

Features will be apparent to those of skill in the art by describing in detail exemplary embodiments with reference to the attached drawings in which:

FIG. 1 illustrates an equivalent circuit diagram of a variable resistance Memory device according to an embodiment;

FIG. 2 illustrates a schematic perspective view of a variable resistance memory device according to an embodiment;

FIG. 3 illustrates a schematic perspective view of a unit memory cell of a variable resistance memory device according to an embodiment;

FIG. 4 illustrates a circuit diagram of a unit memory cell of a variable resistance memory device according to an embodiment;

FIG. 5 illustrates a graph showing the current and voltage properties of a variable resistance memory device according to an embodiment;

FIG. 6 illustrates a perspective view of a variable resistance memory device according to an embodiment;

FIG. 7 illustrates a cross-sectional view taken along a line X-X′ and a line Y-Y′ of FIG. 6;

FIG. 8 illustrates a graph showing set and reset programming with respect to a variable resistance layer of a variable resistance memory device according to an embodiment;

FIG. 9 schematically illustrates an ion diffusion path of a variable resistance layer according to a voltage applied to a memory cell of a variable resistance memory device according to an embodiment;

FIG. 10 illustrates a graph schematically showing a voltage-current curve of a selection device layer of a variable resistance memory device according to an embodiment;

FIG. 11 illustrates a perspective view of a variable resistance memory device according to another embodiment;

FIG. 12 illustrates a cross-sectional view taken along a line X-X′ and a line Y-Y′ of FIG. 11;

FIG. 13 illustrates a perspective view of a variable resistance memory device according to another embodiment;

FIG. 14 illustrates a cross-sectional view taken along a line X-X′ and a line Y-Y′ of FIG. 13;

FIGS. 15 to 18 illustrate cross-sectional views of stages in a manufacturing method of a variable resistance memory device according to an embodiment;

FIGS. 19A to 19D illustrate perspective view showing a cell structure of a variable resistance memory device according to an embodiment;

FIG. 20 illustrates a perspective view of a variable resistance memory device according to another embodiment;

FIG. 21 illustrates cross-sectional views taken along a line 2X-2X′ and a line 2Y-2Y′ of FIG. 20;

FIG. 22 illustrates a perspective view of a variable resistance memory device according to an embodiment;

FIG. 23 illustrates a cross-sectional view taken along a line X-X′ of FIG. 22;

FIG. 24 illustrates a block diagram of a configuration of a variable resistance memory device according to an embodiment;

FIG. 25 illustrates a block diagram of a configuration of a data processing system including a variable resistance memory device according to an embodiment; and

FIG. 26 illustrates a block diagram of a configuration of a data processing system including a variable resistance memory device according to another embodiment.

### DETAILED DESCRIPTION

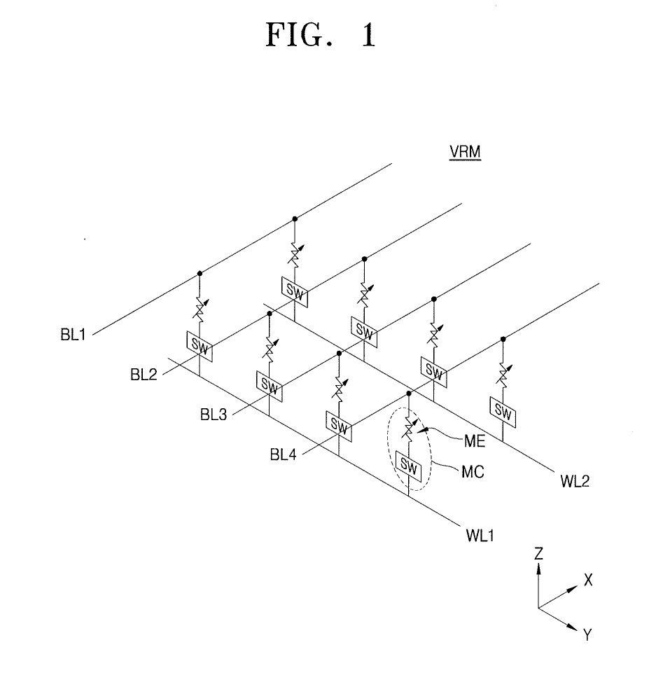

FIG. 1 illustrates an equivalent circuit diagram of a variable resistance memory device VRM according to an embodiment.

For example, the variable resistance memory device VRM may include word lines WL1 and WL2 extending in a first direction (Y direction) and spaced apart from each other in a second direction (X direction) perpendicular to the first direction. The variable resistance memory device VRM may include bit lines BL1, BL2, BL3, and BL4 spaced apart from the word lines WL1 and WL2 in a third direction (Z direction), extending in the second direction, and spaced apart from each other in the first direction. The third direction may be a direction perpendicular to the first direction and the second direction.

The word lines WL1 and WL2 may be referred to as first electrode lines (or first signal lines). The bit lines BL1, BL2, BL3, and BL4 may be referred to as second electrode lines (or second signal lines). In an implementation, the word lines WL1 and WL2 may be referred to as second electrode lines (or second signal lines) and the bit lines BL1, BL2, BL3, and BL4 may be referred to as first electrode lines (or first signal lines).

A memory cell MC may be arranged between each of the bit lines BL1, BL2, BL3, and BL4 and each of the word lines WL1 and WL2. The memory cell MC may be arranged at an intersection between each of the bit lines BL1, BL2, BL3, and BL4 and each of the word lines WL1 and WL2, and may include a variable resistance layer ME for storing information and a selection device SW for selecting the memory cell MC. The selection device SW may be referred to as a switching device or an access device.

The memory cell MC may be arranged in an identical structure along the third direction. The memory cell MC may configure or form a memory cell array of a single layer in the first direction and the second direction. When the memory cell arrays are stacked in the third direction, the variable resistance memory device VRM may include memory cell arrays in a three-dimensional (3D) vertical structure.

In the memory cell MC between the word line WL1 and the bit line BL4, the selection device SW may be electrically connected to the word line WL1, the variable resistance layer ME may be electrically connected to the bit line BL4, and the variable resistance layer ME and the selection device SW may be connected in series. In an implementation, in the memory cell MC, the positions of the selection device SW and the variable resistance layer ME may be switched. For example, in the memory cell MC, the variable resistance layer ME may be connected to the word line WL1 and the selection device SW may be connected to the bit line BL4.

A method of operating the variable resistance memory device VRM is briefly described. When a voltage is applied to the variable resistance layer ME of the memory cell MC via the word lines WL1 and WL2 and the bit lines BL1, BL2, BL3, and BL4, current may flow through the variable resistance layer ME. For example, the variable resistance layer ME may include a phase-change material layer capable of reversibly transiting between a first state and a second state. In an implementation, a suitable variable resistance material having a resistance value varying according to an applied voltage may be used. For example, in a selected memory cell MC, resistance of the variable resistance layer ME may be reversibly transited between the first state and the second state according to a voltage applied to the variable resistance layer ME.

According to a change in the resistance of the variable resistance layer ME, the memory cell MC may memorize digital information such as “0” or “1” and erase the digital information from the memory cell MC. For example, in the memory cell MC, data may be written in a high resistance state “0” and a low resistance state “1”. In this state, writing from the high resistance state “0” to the low resistance state “1” may be referred to as a “set operation”, and writing from the low resistance state “1” to the high resistance state “0” may be referred to as a “reset operation”. In an implementation, the memory cell MC according to the present embodiment may store various resistance states.

A certain memory cell MC may be addressed according to the selection of the word lines WL1 and WL2 and the bit lines BL1, BL2, BL3, and BL4, and the memory cell MC may be programmed by applying a certain signal between the word lines WL1 and WL2 and the bit lines BL1, BL2, BL3, and BL4. Information according to the resistance value of the variable resistance layer ME of the memory cell MC, e.g., programmed information, may be read by measuring a current value through the bit lines BL1, BL2, BL3, and BL4.

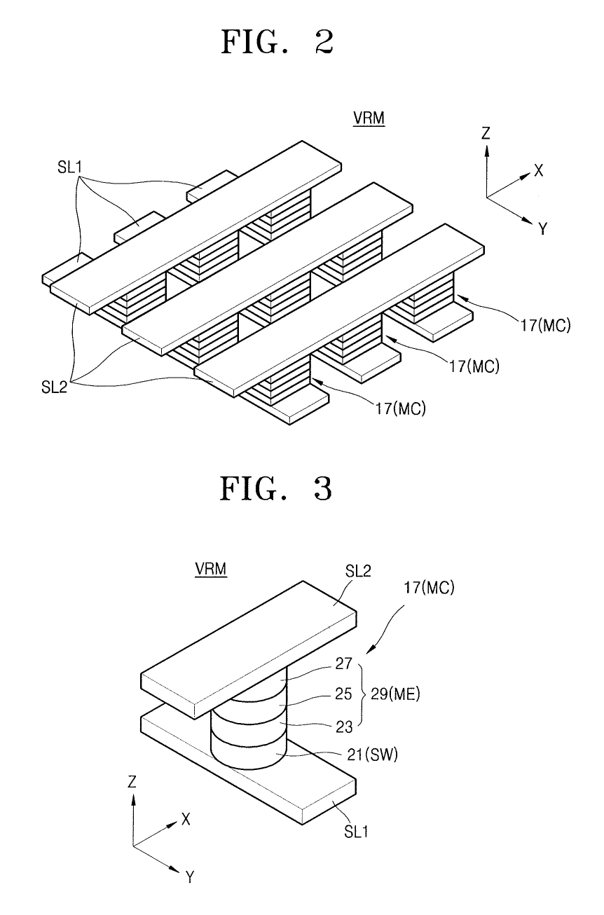

FIG. 2 illustrates a schematic perspective view of the variable resistance memory device VRM of FIG. 1.

For example, the variable resistance memory device VRM may include a plurality of memory cell MCs. The memory cell MC may be configured as or may have or include a cell structure 17. The memory cells MCs of the variable resistance memory device VRM may constitute or form a memory cell array. The variable resistance memory device VRM may include a plurality of first electrode lines SL1 and a plurality of second electrode lines SL2. The first electrode lines SL1 and the second electrode lines SL2 may substantially form a right angle to each other and the memory cell MC may be defined at each intersection.

The first electrode lines SL1 may extend in the first direction (Y direction) and may be spaced apart from each other in the second direction (X direction). The second electrode lines SL2 may be spaced apart from the first electrode lines SL1 in the third direction (Z direction). The second electrode lines SL2 may be disposed on or above the first electrode lines SL1, and may extend in the second direction and may be spaced apart from each other in the first direction. The first electrode lines SL1 and the second electrode lines SL2 may be arrayed in a desired form. For example, when the first electrode lines SL1 are arrayed or extend in a row direction, the second electrode lines SL2 may be arrayed or extend in a column direction. When the first electrode lines SL1 are word lines, the second electrode lines SL2 may be bit lines.

The memory cell MC may include the cell structure 17 including the variable resistance layer ME as described above. The cell structure 17 may include one or more material layers as described below. The cell structure 17 is described below in detail. The memory cell MC may store digital information. The memory cell MC may store digital information by the resistance change between two states including the high resistance state and the low resistance state, as described above.

FIG. 3 illustrates a schematic perspective view of a unit memory cell of the variable resistance memory device VRM of FIG. 1.

For example, the unit memory cell MC of the variable resistance memory device VRM may include the selection device SW and the variable resistance layer ME between the first electrode line SL1, e.g., the word line, and the second electrode line SL2, e.g., the bit line. The variable resistance layer ME may include a variable resistance pattern structure 29. In an implementation, the selection device SW may be omitted. The selection SW may include a selection device layer 21. The selection device layer 21 is described below in detail.

The variable resistance pattern structure 29 may have a stack pattern including a first pattern 23, a second pattern 25, and a third pattern 27. In an implementation, as illustrated in FIG. 3, the variable resistance pattern structure 29 may have a stack pattern of three patterns. In an implementation, the variable resistance pattern structure 29 may include the variable resistance layer ME, as described above.

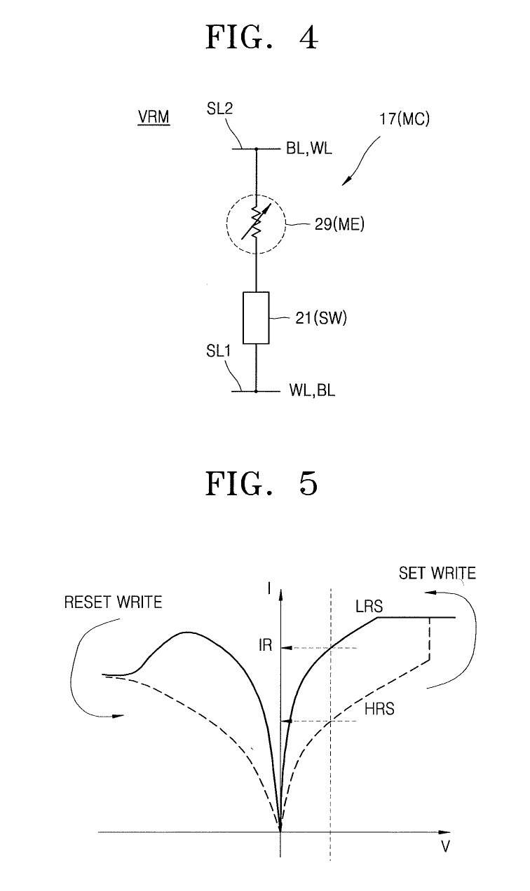

FIG. 4 illustrates a circuit diagram of a unit memory cell of the variable resistance memory device VRM of FIG. 1.

For example, the unit memory cell MC of the variable resistance memory device VRM may include the variable resistance layer ME and the selection device SW between the bit line BL and the word line WL, as described above. In an implementation, as described above, the selection device SW may be omitted.

The selection device SW may include the selection device layer 21, as described above. The selection device layer 21 may be, e.g., a current steering element that may control a flow of current. The selection device layer 21 may be, e.g., an ovonic threshold switching device. The ovonic threshold switching device may include, e.g., at least two of silicon (Si), germanium (Ge), antimony (Sb), tellurium (Te), selenium (Se), indium (In), and tin (Sn) based on arsenic (As), or at least two of silicon (Si), germanium (Ge), antimony (Sb), tellurium (Te), arsenic (As), indium (In), and tin (Sn) based on selenium (Se).

In an implementation, the selection device layer 21 may be formed of, e.g., a silicon-based material, a transition metal oxide, and chalcogenide glasses. In an implementation, the selection device layer 21 may have, e.g., a metal/silicon/metal structure (MSM selector). In an implementation, the selection device layer 21 may include, e.g., a silicon diode, an oxide diode, or a tunneling diode. In an implementation, the selection device layer 21 may be, e.g., a unidirectional diode, a bidirectional diode, or a transistor.

The first electrode line SL1 may be the word line WL or the bit line BL. The second electrode line SL2 may be the bit line BL or the word line WL. The variable resistance pattern structure 29 may include the variable resistance layer ME. When the memory cell MC includes the variable resistance layer ME, the memory cell MC may be a resistive memory cell or a resistive RAM (RRAM) cell.

In an implementation, when the variable resistance layer ME includes a phase change layer, e.g., Ge—Sb—Te (GST) layer, between the upper and lower electrodes, in which resistance varies according to a temperature, the variable resistance memory device VRM may be PRAM. In an implementation, when the variable resistance layer ME includes a resistance change layer, e.g., a transition metal oxide (complex metal oxide), between the upper and lower electrodes, the variable resistance memory device VRM may be RRAM.

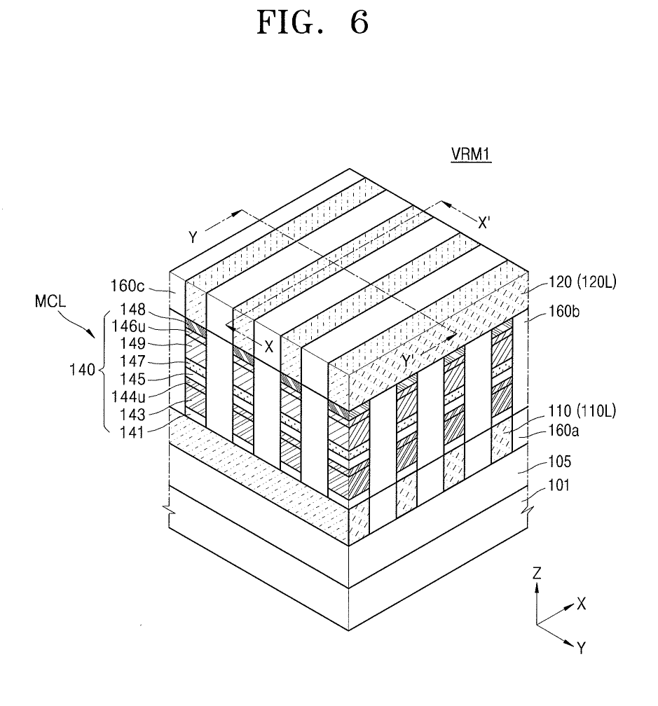

FIG. 5 illustrates a graph showing the current and voltage properties of the variable resistance memory device VRM of FIG. 1.

For example, the variable resistance memory device VRM of FIGS. 1 to 4 shows a switching behavior of a set write state from a high resistance state (HRS) to a low resistance state (LRS) as a voltage increases. The variable resistance memory device VRM shows a switching behavior of a reset write state from the low resistance state (LRS) to the high resistance state (HRS) as a voltage decreases.

The variable resistance memory device VRM of FIGS. 1 to 4 may determine the low resistance state or the high resistance state by detecting a write current IR at a certain voltage. As such, the variable resistance memory device VRM of FIG. 1 may implement digital information that turns on or off in the low resistance state or the high resistance state.

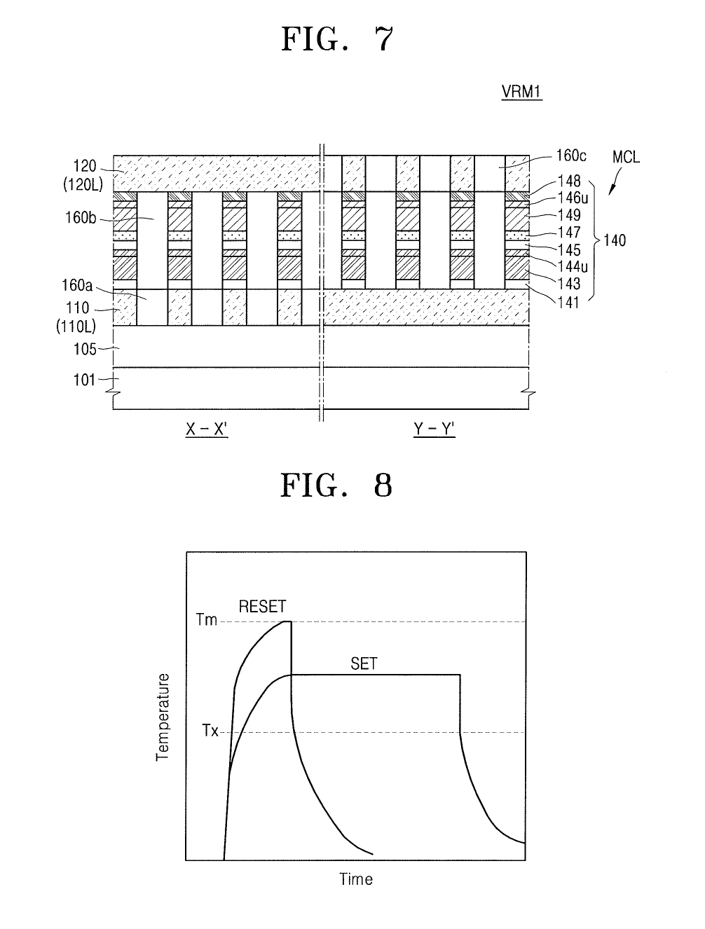

FIG. 6 illustrates a perspective view of a variable resistance memory device VRM1 according to an embodiment. FIG. 7 illustrates a cross-sectional view taken along a line X-X′ and a line Y-Y′ of FIG. 6.

For example, the variable resistance memory device VRML according to the present embodiment may be an implement of the variable resistance memory device VRM of FIGS. 1 to 4. The variable resistance memory device VRM1 may include a first electrode line layer 110L, a second electrode line layer 120L, and a memory cell layer MCL, on a substrate 101. The memory cell layer MCL may be the memory cell MC of FIGS. 1 to 4. When plurally arranged in the first direction (Y direction) and the second direction (X direction), the memory cell layer MCL may be a single-layer memory cell array.

An interlayer insulating layer 105 may be arranged on the substrate 101. The substrate 101 may be, e.g., a wafer or a semiconductor substrate. The substrate 101 may be, e.g., a silicon substrate, a germanium substrate, a silicon-germanium substrate, a silicon-on-insulator (SOI) substrate, or a germanium-on-insulator (GOI) substrate. The interlayer insulating layer 105 may be formed of, e.g., an oxide such as a silicon oxide or a nitride such as a silicon nitride. The interlayer insulating layer 105 may electrically separate the first electrode line layer 110L from the substrate 101.

In an implementation, the interlayer insulating layer 105 may be arranged on the substrate 101. In an implementation, as described below, an integrated circuit layer may be arranged above the substrate 101 and the memory cell layer MCL may be arranged above or on the integrated circuit layer (e.g., such that the integrated circuit layer is between the memory cell layer MCL and the substrate 101). The integrated circuit layer may include, e.g., a peripheral circuit for the operation of a memory cell and/or a core circuit for driving. A structure in which the integrated circuit layer including the peripheral circuit and/or the core circuit is arranged above or on the substrate 101 and the memory cell layer MCL is arranged above or on the integrated circuit layer may be referred to as a Cell on Peri (COP) structure, which is described below in detail.

The first electrode line layer 110L may include a plurality of first electrode lines 110 extending in the first direction (Y direction) and parallel to one another. The second electrode line layer 120L may include a plurality of second electrode lines 120 extending in the second direction (X direction) crossing the first direction and parallel to one another. The first direction and the second direction may perpendicularly cross each other.

In view of the operation of the variable resistance memory device VRM1, the first electrode lines 110 may correspond to the word lines WL1 and WL2 of FIG. 1, and the second electrode lines 120 may correspond to the bit lines BL1 to BL4 of FIG. 1. In an implementation, reversely, the first electrode lines 110 may correspond to the bit lines BL1 to BL4 of FIG. 1 and the second electrode lines 120 may correspond to the word lines WL1 and WL2 of FIG. 1.

The first electrode lines 110 and the second electrode line 120 may be formed of, e.g., impurity-doped polysilicon, metal, conductive metal nitride, or a combination thereof. In an implementation, the first electrode lines 110 and the second electrode line 120 may be formed of, e.g., W, WN, Au, Ag, Cu, Al, TiAlN, Ir, Pt, Pd, Ru, Zr, Rh, Ni, Co, Cr, Sn, Zn, ITO, an alloy thereof, or a combination thereof. The first electrode lines 110 and the second electrode line 120 may include a metal layer or a conductive barrier layer covering at least part of the metal layer. The conductive barrier layer may be formed of, e.g., Ti, TiN, Ta, TaN, or a combination thereof.

The memory cell layer MCL may include a plurality of cell structures 140 spaced apart in the first direction and the second direction. The cell structure 140 may constitute the memory cell MC of FIGS. 1 to 4. The first electrode lines 110 and the second electrode line 120 may cross each other. The cell structures 140 may be arranged at intersections of the first electrode lines 110 and the second electrode lines 120 between the first electrode line layer 110L and the second electrode line layer 120L.

The cell structure 140 is illustrated in the drawings as a pillar structure having a square column shape. In an implementation, as described below in detail, as the cell structure 140 is formed in one-time etching process, the cell structure 140 may have various column shapes such as a cylindrical column, an elliptical column, a polygonal column, or the like. The cell structure 140 may include a first cell structure formed in the first direction (Y direction) and a second cell structure formed in the second direction (X direction). As described below, the first cell structure and the second cell structure that are formed in the one-time etching process may have the same shape and structure. When the shape or structure of the cell structure 140 is identical in the first direction (Y direction) and the second direction (X direction) on the substrate 101, the properties of the variable resistance memory device VRM1 may be improved.

The cell structure 140 may have a structure in which a lower portion (e.g., proximate to the substrate 101) is wider than an upper portion (e.g., distal to the substrate 101) or the upper portion is wider than the lower portion according to an etching process. When the etching process is precisely controlled, a side surface of the cell structure 140 may be formed to be almost vertical so that the upper portion and the lower portion hardly have a difference in their width. In an implementation, the cell structure 140 may have a structure in which the lower portion is wider than the upper portion or the upper portion is wider than the lower portion, as described above.

The cell structure 140 may include, e.g., a lower electrode layer 141, a selection device layer 143, an intermediate electrode layer 145, a heating electrode layer 147, a variable resistance layer 149, an upper electrode layer 148, and blocking layers 144u and 146u. The cell structure 140 may include, as described above, the selection device layer 21 of FIGS. 3 and 4 and the variable resistance pattern structure 29 of FIGS. 3 and 4.

The blocking layers 144u and 146u may be protection layers to help protect the memory cell layer MCL, e.g., the selection device layer 143 and the variable resistance layer 149. The blocking layers 144u and 146u may help protect the selection device layer 143 and the variable resistance layer 149, thereby preventing undesirable degradation of properties of the cell structure 140.

The blocking layer 146u may be formed on an upper surface of the variable resistance layer 149 (e.g., such that the variable resistance layer 149 is between the blocking layer 146u and the substrate 101). The blocking layer 146u may be formed on a lower surface of the upper electrode layer 148 (e.g., such that the blocking layer 146u is between the upper electrode layer 148 and the variable resistance layer 149). The blocking layer 146u, as a first blocking layer, may be referred to as a first upper blocking layer. The blocking layer 144u may be on an upper surface of the selection device layer 143 (e.g., such that the selection device layer 143 is between the blocking layer 144u and the substrate 101). The blocking layer 144u may be formed on a lower surface of the intermediate electrode layer 145 (e.g., such that the blocking layer 144u is between the intermediate electrode layer 145 and the selection device layer 143). The blocking layer 144u, as a second blocking layer, may be referred to as a second upper blocking layer. In an implementation, the blocking layer 144u may be omitted.

The blocking layers 144u and 146u each may include, e.g., a metal layer for protecting the selection device layer 143 and the variable resistance layer 149. The blocking layers 144u and 146u each may include, e.g., a metal layer or a carbon-based or carbon-containing conductive layer. The blocking layers 144u and 146u each may include, e.g., a refractive metal layer or a nitride layer including a refractive metal. In an implementation, the blocking layers 144u and 146u each may be formed of, e.g., TiN, TiSiN, TiAlN, TaSiN, TaAlN, TaN, WSi, WN, TiW, MoN, NbN, TiBN, ZrSiN, WSiN, WBN, ZrAlN, MoAlN, TiAl, TiON, TiAlON, WON, TaON, carbon (C), silicon carbide (SiC), silicon carbon nitride (SiCN), carbon nitride (CN), titanium carbon nitride (TiCN), tantalum carbon nitride (TaCN), or a combination thereof.

In an implementation, the variable resistance layer 149 (the ME of FIGS. 1, 3, and 4) may include a phase change material that reversibly changes between an amorphous state and a crystalline state according to a heating time. For example, the variable resistance layer 149 may have a phase that reversibly changes by Joule heat generated by a voltage applied between opposite ends of the variable resistance layer 149 and may include a material having resistance varying according to a phase change.

For example, the phase change material may be in a high resistance state on an amorphous phase and in a low resistance state at a crystalline phase. The variable resistance layer 149 may store data by defining the high resistance state to be “0” and the low resistance state to be “1”.

In an implementation, the variable resistance layer 149 may include a chalcogenide material as the phase change material. In an implementation, the variable resistance layer 149 may include, e.g., Ge—Sb—Te (GST). In this regard, a chemical composition notation using a hyphen (-) may indicate elements included in a specific mixture or compound and may denote all chemical structures including the indicated elements. For example, Ge—Sb—Te may be a material such as Ge₂Sb₂Te₅, Ge₂Sb₂Te₇, Ge₁Sb₂Te₄, or Ge₁Sb₄Te₇.

The variable resistance layer 149 may include various chalcogenide materials in addition to the above-described Ge—Sb—Te (GST). The variable resistance layer 149 may include various phase change materials in addition to the above-described Ge—Sb—Te (GST). In an implementation, the variable resistance layer 149 may include, e.g., at least one of Ge—Te, Sb—Te, In—Se, Ga—Sb, In—Sb, As—Te, Al—Te, Bi—Sb—Te (BST), In—Sb—Te (IST), Ge—Sb—Te, Te—Ge—As, Te—Sn—Se, Ge—Se—Ga, Bi—Se—Sb, Ga—Se—Te, Sn—Sb—Te, In—Sb—Ge, In—Ge—Te, Ge—Sn—Te, Ge—Bi—Te, Ge—Te—Se, As—Sb—Te, Sn—Sb—Bi, Ge—Te—O, Te—Ge—Sb—S, Te—Ge—Sn—O, Te—Ge—Sn—Au, Pd—Te—Ge—Sn, In—Se—Ti—Co, Ge—Sb—Te—Pd, Ge—Sb—Te—Co, Sb—Te—Bi—Se, Ag—In—Sb—Te, Ge—Sb—Se—Te, Ge—Sn—Sb—Te, Ge—Te—Sn—Ni, Ge—Te—Sn—Pd, Ge—Te—Sn—Pt, In—Sn—Sb—Te, and As—Ge—Sb—Te, or a combination thereof.

Each element constituting the variable resistance layer 149 may have various chemical composition ratios (stoichiometry). A crystallization temperature, a melting point, a phase change rate according to crystallization energy, and information retention of the variable resistance layer 149 may be controlled based on the chemical composition ratio of each element.

In an implementation, the variable resistance layer 149 may be doped with impurities including, e.g., nitrogen (N), oxygen (O), silicon (Si), carbon (C), boron (B), dysprosium (Dy), or a combination thereof. In an implementation, the variable resistance layer 149 may further include metal. In an implementation, the variable resistance layer 149 may include, e.g., at least one of aluminum (Al), gallium (Ga), zinc (Zn), titanium (Ti), chromium (Cr), manganese (Mn), iron (Fe), cobalt (Co), nickel (Ni), molybdenum (Mo), ruthenium (Ru), palladium (Pd), hafnium (Hf), tantalum (Ta), iridium (Ir), platinum (Pt), zirconium (Zr), thallium (Tl), palladium (Pd), and polonium (Po). These metal materials may help increase electrical conductivity and thermal conductivity of the variable resistance layer 149, and accordingly, may help increase a crystallization speed so that a set speed may be increased. Furthermore, the metal materials may help improve the information retention properties of the variable resistance layer 149.

The variable resistance layer 149 may have a multilayer structure in which two or more layers having different physical properties are stacked. The number or thickness of a plurality of layers may be freely selected. A barrier layer may be further formed between the layers. The barrier layer may help prevent diffusion of a material between the layers. For example, the barrier layer may help decrease diffusion of a preceding layer when a subsequent layer is formed among the layers.

In an implementation, the variable resistance layer 149 may have a super-lattice structure in which a plurality of layers including different materials are alternately stacked. For example, the variable resistance layer 149 may have a structure in which a first layer formed of Ge—Te and a second layer formed of Sb—Te are alternately stacked. In an implementation, the materials of the first layer and the second layer may respectively include the above-described various materials.

In an implementation, a phase change material may serve as the variable resistance layer 149. In an implementation, the variable resistance layer 149 of the variable resistance memory device VRM1 may include various materials having resistance change properties.

In an implementation, when the variable resistance layer 149 includes a transition metal oxide as the resistance change layer, the variable resistance memory device VRM1 may be RRAM. At least one electrical path may be generated or destroyed by a programming operation in the variable resistance layer 149 including a transition metal oxide. When the electrical path is generated, the variable resistance layer 149 may have a low resistance value, and when the electrical path is destroyed, the variable resistance layer 149 may have a high resistance value. The variable resistance memory device VRM1 may store data by using a difference in the resistance value of the variable resistance layer 149.

When the variable resistance layer 149 is formed of a transition metal oxide, the transition metal oxide may include, e.g., at least one metal of Ta, Zr, Ti, Hf, Mn, Y, Ni, Co, Zn, Nb, Cu, Fe, and Cr. For example, the transition metal oxide may be a single layer or a multiple layer formed of at least one material of Ta₂O₅₋ₓ, TiO₂₋ₓ HfO₂₋ₓ, MnO₂₋ₓ, Y₂O₃₋ₓ, NiO_{1-y}, Nb₂O₅₋ₓ, CuO_{1-y}, and Fe₂O₃₋ₓ. In an implementation, in the above-mentioned materials x and y may be selected from ranges of 0≤x≤1.5 and 0≤y≤0.5.

The selection device layer 143 may be a current steering element that may help control a flow of current. The selection device layer 143 may include a material layer having resistance varying according to an amount of a voltage applied between opposite ends of the selection device layer 143. For example, the selection device layer 143 may be, e.g., an ovonic threshold switching device including an ovonic threshold switching (OTS) material. In a brief description of a function of the selection device layer 143 based on the OTS material, when a voltage less than a threshold voltage Vt is applied to the selection device layer 143, the selection device layer 143 maintains a high resistance state in which current hardly flows. When a voltage greater than the threshold voltage Vt is applied to the selection device layer 143, the selection device layer 143 may be in a low resistance state and thus current begins to flow. Furthermore, when the current flowing through the selection device layer 143 becomes less than a holding current, the selection device layer 143 may be changed to the high resistance state.

The selection device layer 143 may include a chalcogenide switching material as the OTS material. For example, the chalcogen elements characteristically have divalent bonding and lone pair electron. The divalent bonding leads to the formation of a chain and ring structure by bonding chalcogen elements to form a chalcogenide material, whereas the lone pair electron provides an electron source for forming a conductive filament. For example, 3- and 4-modifiers such as aluminum (Al), gallium (Ga), indium (In), germanium (Ge), tin (Sn), silicon (Si), phosphorus (P), arsenic (As) and antimony (Sb) determine structural strength of a chalcogenide material by entering the chain and ring structure of an chalcogen element, and classifies the chalcogenide material into a switching material and a phase change material according to the capacity of crystallization or other structural rearrangement.

The heating electrode layer 147 may be between the intermediate electrode layer 145 and the variable resistance layer 149 to contact the variable resistance layer 149. The heating electrode layer 147 may heat the variable resistance layer 149 in the set or reset operation. The heating electrode layer 147 may include a conductive material capable of generating heat sufficient to cause a phase change to the variable resistance layer 149 without reacting to the variable resistance layer 149. In an implementation, the heating electrode layer 147 may include a carbon-containing conductive material. In an implementation, the heating electrode layer 147 may include, e.g., a refractive metal layer or a nitride layer including a refractive metal. In an implementation, the heating electrode layer 147 may be formed of, e.g., TiN, TiSiN, TiAlN, TaSiN, TaAlN, TaN, WSi, WN, TiW, MoN, NbN, TiBN, ZrSiN, WSiN, WBN, ZrAlN, MoAlN, TiAl, TiON, TiAlON, WON, TaON, carbon (C), silicon carbide (SiC), silicon carbon nitride (SiCN), carbon nitride (CN), titanium carbon nitride (TiCN), tantalum carbon nitride (TaCN), or a combination thereof.

The lower electrode layer 141, the intermediate electrode layer 145, and the upper electrode layer 148 are layers functioning as current paths and may be formed of a conductive material. In an implementation, the lower electrode layer 141, the intermediate electrode layer 145, and the upper electrode layer 148 may be formed of, e.g., metal, a conductive metal nitride, a conductive metal oxide, or a combination thereof.

The lower electrode layer 141 and the upper electrode layer 148 may be selectively formed. In an implementation, the lower electrode layer 141 and/or the upper electrode layer 148 may be omitted. In order to help prevent contamination or a contact defect that may be generated as the selection device layer 143 and the variable resistance layer 149 directly contact the first and second electrode lines 110 and 120, the lower electrode layer 141 and the upper electrode layer 148 may be included between the first and second electrode lines 110 and 120, the selection device layer 143, and the blocking layer 146u. In addition, as described above, the blocking layer 146u may be formed on the variable resistance layer 149, and the variable resistance layer 149 may be protected.

The intermediate electrode layer 145 may help prevent transfer of heat from the heating electrode layer 147 to the selection device layer 143. The selection device layer 143 may include a chalcogenide switching material in an amorphous state. In an implementation, the thickness and width of each of the variable resistance layer 149, the selection device layer 143, the heating electrode layer 147, and the intermediate electrode layer 145, and the intervals between the variable resistance layer 149, the selection device layer 143, the heating electrode layer 147, and the intermediate electrode layer 145, may decrease according to the downscaling trend of the variable resistance memory device VRM1.

Accordingly, in the operation process of the variable resistance memory device VRM1, when the heating electrode layer 147 is heated to cause a phase change to the variable resistance layer 149, the selection device layer 143 arranged adjacent thereto could be affected by the heat. For example, the selection device layer 143 could be partially crystallized by the heat from the heating electrode layer 147 adjacent thereto, generating degradation and damage of the selection device layer 143.

In the variable resistance memory device VRM1 of the present embodiment, the intermediate electrode layer 145 may be thick so that the heat of the heating electrode layer 147 is not transferred to the selection device layer 143. In an implementation, the intermediate electrode layer 145 may be formed to be thicker than the lower electrode layer 141 or the upper electrode layer 148 for the heat shielding function.

In an implementation, the intermediate electrode layer 145 may have a thickness of, e.g., about 10 nm to about 100 nm. In an implementation, the intermediate electrode layer 145 may include at least one thermal barrier layer for the heat shielding function. When the intermediate electrode layer 145 includes two or more thermal barrier layers, the intermediate electrode layer 145 may have a structure in which the thermal barrier layer and an electrode material layer are alternately stacked. In addition, the blocking layer 144u may be formed on the selection device layer 143 to help prevent the heat of the heating electrode layer 147 from being transferred to the selection device layer 143.

A first insulating layer 160a may be arranged between the first electrode lines 110, and a second insulating layer 160b may be arranged between the cell structures 140 of the memory cell layer MCL. In an implementation, a third insulating layer 160c may be arranged between the second electrode lines 120. The first to third insulating layers 160a to 160c may be formed as insulating layers of the same material or at least one of the first to third insulating layers 160a to 160c may be formed as an insulating layer of a different material. The first to third insulating layers 160a to 160c may be formed of, e.g., a dielectric material of an oxide or nitride, and may have a function of electrically splitting devices of the respective layers. In an implementation, an air gap may be formed instead of the second insulating layer 160b. When an air gap is formed, an insulating liner having a certain thickness may be formed between the air gap and the cell structures 140.

FIG. 8 illustrates a graph showing set and reset programming with respect to a variable resistance layer of the variable resistance memory device VRM1.

For example, when a phase change material of the variable resistance layer 149 of FIGS. 6 and 7 is heated to a temperature between a crystallization temperature Tx and a melting point Tm for a certain time and then gradually cooled, the phase change material may be in a crystalline state. The crystalline state may be referred to as a “set state”, in which data “0” is stored. In contrast, when the phase change material is heated to a temperature over the melting point Tm and then cooled quickly, the phase change material may be in an amorphous state. The amorphous state may be referred to a “reset state”, in which data “1” is stored as described above.

Accordingly, data may be stored by supplying current to the variable resistance layer 149, and the data may be read out by measuring a resistance value of the variable resistance layer 149. The heating temperature of a phase change material is proportional to the amount of current. As the amount of current increases, it may be difficult to achieve a high degree of integration. Transition to an amorphous state could require a larger amount of current than transition to the crystalline state, and power consumption of the variable resistance memory device VRM1 could increase. Accordingly, to reduce power consumption, changing to a crystalline or amorphous state by heating the phase change material may proceed with a small current amount. For example, to achieve a high degree of integration, reducing current, e.g., a reset current, for transition to the amorphous state may be desirable.

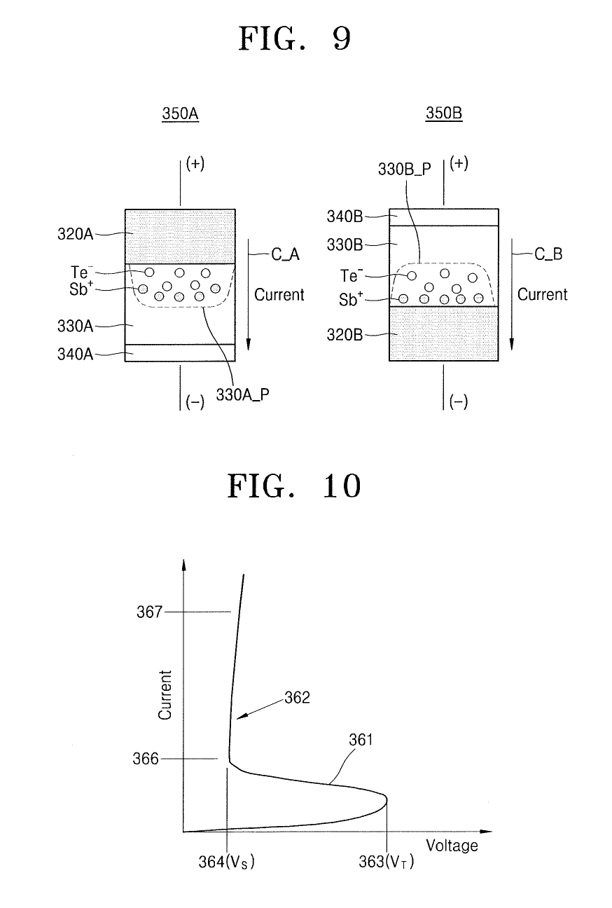

FIG. 9 schematically illustrates an ion diffusion path of a variable resistance layer according to a voltage applied to the memory cell MC of the variable resistance memory device VRM1 of FIG. 6.

For example, a first memory cell 350A may include a first electrode 320A, a variable resistance layer 330A, and a second electrode 340A that are sequentially stacked. The first electrode 320A may include a conductive material that generates heat sufficient to cause a phase change to the variable resistance layer 330A, and may correspond to the heating electrode layer 147 in FIGS. 6 and 7. In the first memory cell 350A, a positive voltage may be applied to the first electrode 320A and a negative voltage may be applied to the second electrode 340A, as indicated by a first arrow C_A, current may flow from the first electrode 320A to the second electrode 340A via the variable resistance layer 330A.

Heat may be generated in the first electrode 320A by current flowing through the first electrode 320A. Accordingly, a phase change may be generated from a part 330A_P of the variable resistance layer 330A adjacent to a boundary between the first electrode 320A and the variable resistance layer 330A. For example, in the “reset operation” in which the part 330A_P of the variable resistance layer 330A is changed from the crystalline state, e.g., a low resistance state, to the amorphous state, e.g., a high resistance state, cations and anions in the part 330A_P may be diffused at different speeds by an applied voltage. For example, in the part 330A_P of the variable resistance layer 330A, the diffusion speed of cations, e.g., antimony ions (Sb⁺), may be relatively faster than the diffusion speed of anions, e.g., tellurium ions (Te⁻). Accordingly, the antimony ions Sb⁺ may be more diffused in a direction toward the second electrode 340A to which a negative voltage is applied. The diffusion speed of the tellurium ions Te⁻ in a direction toward the first electrode 320A may be faster than the diffusion speed of the antimony ions Sb⁺ in a direction toward the second electrode 340A.

In contrast, a second memory cell 350B may include a first electrode 320B, a variable resistance layer 330B, and a second electrode 340B. As a negative voltage is applied to the first electrode 320B and a positive voltage is applied to the second electrode 340B, as indicated by a second arrow C_B, current may flow from the second electrode 340B to the first electrode 320B via the variable resistance layer 330B.

Heat may be generated in the first electrode 320B by the current flowing through the first electrode 320B. Accordingly, a phase change may be generated in a part 330B_P of the variable resistance layer 330B adjacent to a boundary between the first electrode 320B and the variable resistance layer 330B. In this state, in the part 330B _P of the variable resistance layer 330B, the diffusion speed of antimony ions Sb⁺ may be relatively faster than the diffusion speed of tellurium ions Te⁻, and the antimony ions Sb⁺ may be more diffused in a direction toward the first electrode 320B to which a negative voltage is applied.

Accordingly, in the case of the second memory cell 350B, the concentration of antimony ions Sb⁺ may be relatively high around the boundary between the first electrode 320B and the variable resistance layer 330B, and a local concentration change may occur in the variable resistance layer 330B. In contrast, in the case of the first memory cell 350A, the concentration of tellurium ions Te⁻ is relatively high around the boundary between the first electrode 320A and the variable resistance layer 330A, a local concentration change may occur in the variable resistance layer 330A.

Consequently, the distribution of ions or vacancies in the variable resistance layers 330A and 330B may vary according to the amount of a voltage applied to the variable resistance layers 330A and 330B, the direction of current flowing through the variable resistance layers 330A and 330B, or geometry of the variable resistance layers 330A and 330B and the first electrodes 320A and 320B. The resistance of the variable resistance layers 330A and 330B may vary according to the local concentration change in the variable resistance layers 330A and 330B, in a state even when the same voltage is applied. Accordingly, the first and second memory cells 350A and 350B may have different operating characteristics, e.g., different resistance values.

In an implementation, as illustrated in FIG. 9, the ion diffusion path may be described with an example of antimony ions Sb⁺ and tellurium ions Te⁻. In an implementation, in the description of FIGS. 6 and 7, as in the description of the variable resistance layer 149, the variable resistance layers 330A and 330B may include a chalcogenide material and furthermore may be doped with impurities. Accordingly, a degree of ion diffusion in the variable resistance layers 330A and 330B may further vary according to the type and composition of a material, and the type and concentration of impurities, included in the variable resistance layers 330A and 330B, Accordingly, operating characteristics variation of the first and second memory cells 350A and 350B may be further increased.

FIG. 10 illustrates a graph schematically showing a voltage-current curve of a selection device layer of the variable resistance memory device VRM1 of FIG. 6.

For example, a first curve 361 shows a voltage-current relation in a state when no current flows through the selection device layer 143 of FIGS. 6 and 7. The selection device layer 143 may serve as a switching device having the threshold voltage Vt of a first voltage level 363. When both a voltage and current are 0 and the voltage gradually increases, current may hardly flow through the selection device layer 143 until the voltage reaches the threshold voltage Vt, e.g., the first voltage level 363. However, as soon as the voltage exceeds the threshold voltage Vt, the current flowing through the selection device layer 143 may be rapidly increased, and the voltage applied to the selection device layer 143 may decease to a saturation voltage Vs, e.g., a second voltage level 364.

A second curve 362 indicates a voltage-current relation in a state when current flows through the selection device layer 143. As the current flowing through the selection device layer 143 increases to be greater than a first current level 366, the voltage applied to the selection device layer 143 may increase to be slightly greater than the second voltage level 364.

For example, while the current flowing through the selection device layer 143 considerably increases from the first current level 366 to a second current level 367, the voltage applied to the selection device layer 143 may only slightly increase from the second voltage level 364. For example, once the current starts to flow through the selection device layer 143, the voltage applied to the selection device layer 143 may be almost maintained at the saturation voltage Vs. When the current decreases below a holding current level, e.g., the first current level 366, the selection device layer 143 may be converted back to a resistance state, and thus the current may be effectively blocked until the voltage increases to the threshold voltage Vt.

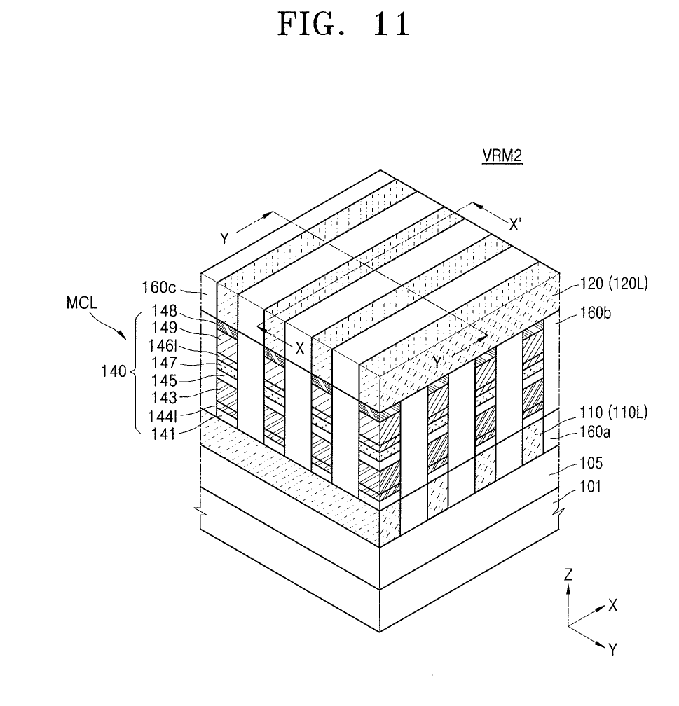

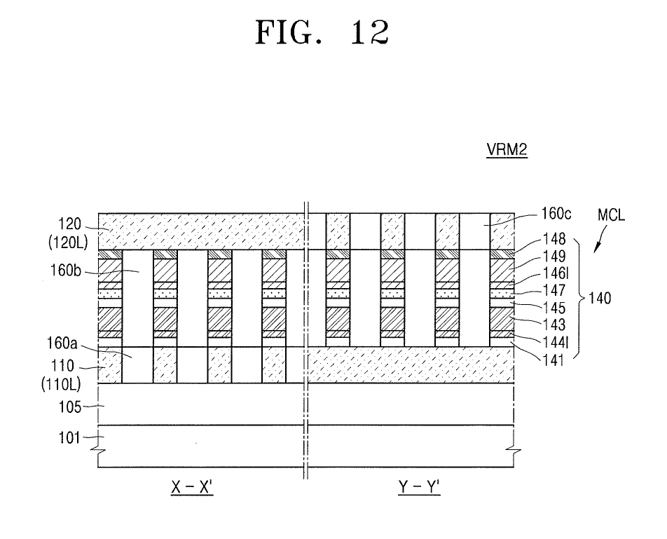

FIG. 11 illustrates a perspective view of a variable resistance memory device VRM2 according to another embodiment. FIG. 12 illustrates a cross-sectional view taken along a line X-X′ and a line Y-Y′ of FIG. 11.

For example, the variable resistance memory device VRM2 according to the present embodiment may be an implementation of the variable resistance memory device VRM of FIGS. 1 to 4. When compared to the variable resistance memory device VRM1 of FIGS. 6 and 7, the variable resistance memory device VRM2 may be the same as the variable resistance memory device VRM1, except for the position of blocking layers 144l and 146l. Accordingly, in the description of FIGS. 11 and 12, the same descriptions as those of FIGS. 6 and 7 may be only briefly presented or omitted.

The memory cell layer MCL of the variable resistance memory device VRM2 may include the cell structures 140 spaced apart from each other in the first direction and the second direction. The cell structure 140 may include, e.g., the lower electrode layer 141, the selection device layer 143, the intermediate electrode layer 145, the heating electrode layer 147, the variable resistance layer 149, the upper electrode layer 148, and the blocking layers 144l and 146l.

The blocking layers 144l and 146l may help protect the memory cell layer MCL, e.g., the selection device layer 143 and the variable resistance layer 149. Accordingly, the blocking layers 144l and 146l may help protect the selection device layer 143 and the variable resistance layer 149, thereby preventing the degradation of properties of the cell structure 140.

The blocking layer 146l may be on a lower surface of the variable resistance layer 149 (e.g., such that the blocking layer 146l is between the variable resistance layer 149 and the substrate 101). The blocking layer 146l may be on an upper surface of the heating electrode layer 147 (e.g., such that the blocking layer 146l is between the variable resistance layer 149 and the heating electrode layer 147). The blocking layer 146l as a first blocking layer may be referred to as a first lower blocking layer. The blocking layer 144l may be on a lower surface of the selection device layer 143 (e.g., such that the blocking layer 144l is between the selection device layer 143 and the substrate 101). The blocking layer 144l may be on an upper surface of the lower electrode layer 141 (e.g., such that the blocking layer 144l is between the selection device layer 143 and the lower electrode layer 141). The blocking layer 144l as a second blocking layer may be referred to as a second lower blocking layer. In an implementation, the blocking layer 144l may be omitted.

The blocking layers 144l and 146l may include a metal layer for protecting the selection device layer 143 and/or the variable resistance layer 149. The blocking layers 144l and 146l may include, e.g., a metal layer or a carbon-containing conductive layer. The materials of the blocking layers 144l and 146l are described in FIGS. 6 and 7, and repeated descriptions thereof are omitted.

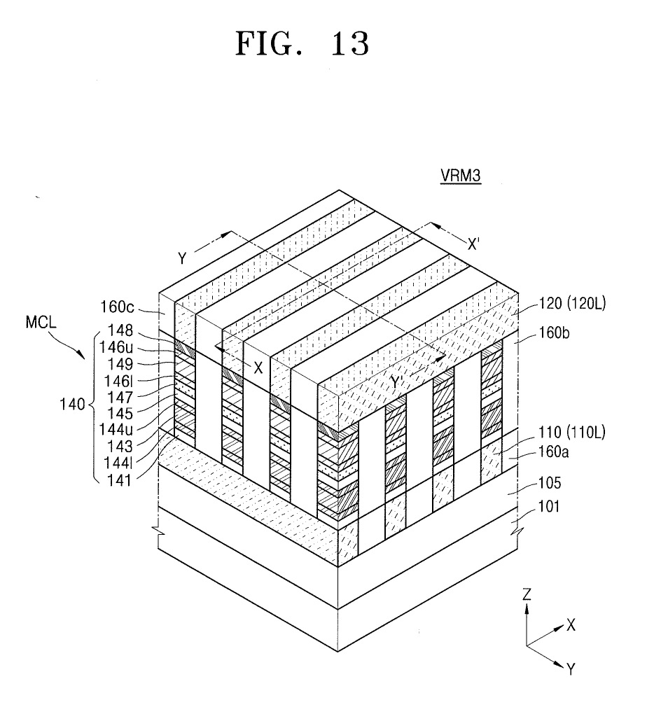

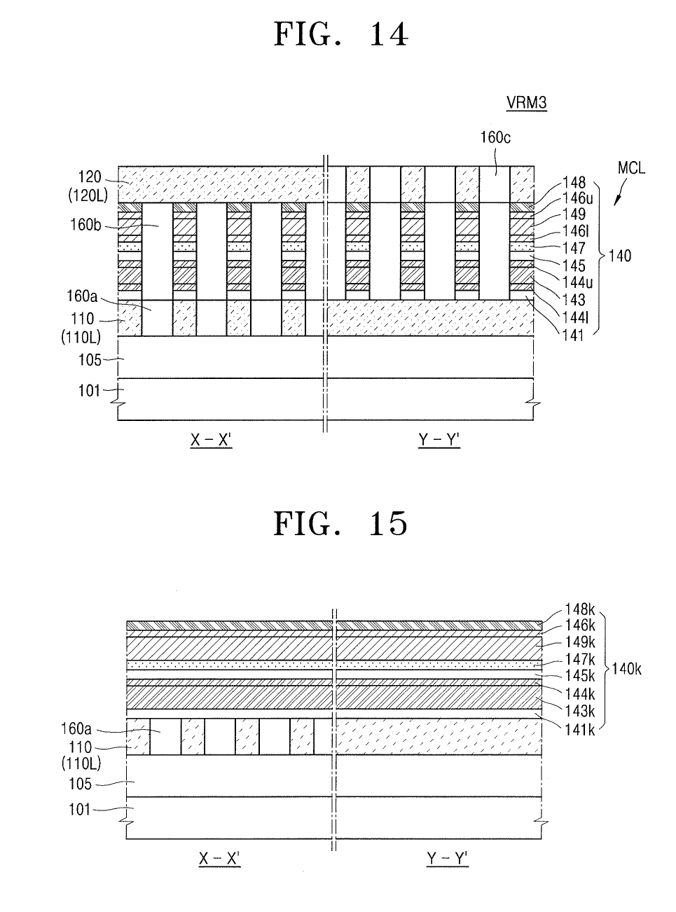

FIG. 13 illustrates a perspective view of a variable resistance memory device VRM3 according to another embodiment. FIG. 14 illustrates a cross-sectional view taken along a line X-X′ and a line Y-Y′ of FIG. 13.

For example, the variable resistance memory device VRM3 according to the present embodiment may be an implementation of the variable resistance memory device VRM of FIGS. 1 to 4. When compared to the variable resistance memory device VRM1 of FIGS. 6 and 7, and the variable resistance memory device VRM2 of FIGS. 11 and 12, the variable resistance memory device VRM3 may be the same as the variable resistance memory device VRM1 and the variable resistance memory device VRM2, except for the position of blocking layers 144l, 144u, 146l, and 146u. Accordingly, in the description of FIGS. 13 and 14, the same descriptions as those of FIGS. 6 and 7, and FIGS. 11 and 12, may be only briefly presented or omitted.

The memory cell layer MCL of the variable resistance memory device VRM3 may include the cell structures 140 spaced apart from each other in the first direction and the second direction. The cell structure 140 may include, e.g., the lower electrode layer 141, the selection device layer 143, the intermediate electrode layer 145, the heating electrode layer 147, the variable resistance layer 149, the upper electrode layer 148, and the blocking layers 144l, 144u, 146l, and 146u.

The blocking layers 144l, 144u, 146l, and 146u may help protect the memory cell layer MCL, e.g., the selection device layer 143 and the variable resistance layer 149. Accordingly, the blocking layers 144l, 144u, 146l, and 146u may help protect the selection device layer 143 and the variable resistance layer 149, thereby preventing the undesirable degradation of properties of the cell structure 140.

The blocking layers 146u and 146l may be respectively formed on upper and lower surfaces of the variable resistance layer 149 (e.g., such that the variable resistance layer 149 is between the blocking layers 146u and 146l). The blocking layer 146u may be on a lower surface of the upper electrode layer 148. The blocking layer 146u may be referred to as a first upper blocking layer. The blocking layer 146l may be on an upper surface of the heating electrode layer 147. The blocking layer 146l may be referred to as a first lower blocking layer.

The blocking layers 144u and 144l may be respectively formed on upper and lower surfaces of the selection device layer 143 (e.g., such that the selection device layer 143 is between the blocking layers 144u and 144l). The blocking layer 144u may be on a lower surface of the intermediate electrode layer 145. The blocking layer 144u may be referred to as a second upper blocking layer. The blocking layer 144l may be on an upper surface of the lower electrode layer 141. The blocking layer 144l may be referred to as a second lower blocking layer.

In an implementation, the blocking layers 144u and 144l may be omitted. The blocking layers 144l, 144u, 146l, and 146u may include a metal layer for protecting the selection device layer 143 and the variable resistance layer 149. The blocking layers 144l, 144u, 146l, and 146u may include, e.g., a carbon-containing conductive layer. The materials of the blocking layers 144l, 144u, 146l, and 146u are described in FIGS. 6 and 7, and FIGS. 11 and 12, and repeated descriptions thereof are omitted.

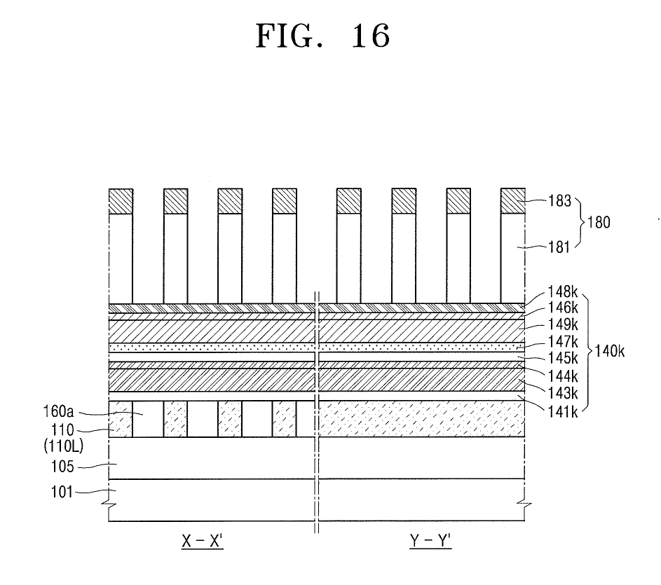

FIGS. 15 to 18 illustrate cross-sectional views of stages in a manufacturing method of a variable resistance memory device according to an embodiment of the present inventive concept. FIGS. 15 to 18 illustrate stages in a method of manufacturing the variable resistance memory device VRM1 of FIGS. 6 and 7.

Referring to FIG. 15, the interlayer insulating layer 105 may be formed on the substrate 101. In an implementation, the interlayer insulating layer 105 may be formed of, e.g., a silicon oxide layer or a silicon nitride layer. The first electrode line layer 110L including a plurality of the first electrode lines 110 extending in the first direction (Y direction) and spaced apart from each other, as described above, may be formed on the interlayer insulating layer 105.

The first electrode lines 110 may be formed by an embossing etch process or a damascene process. The material of the first electrode lines 110 may be the same as that described in FIGS. 6 and 7. The first insulating layer 160a extending in the first direction may be arranged between the first electrode lines 110.

A stack structure 140k may be formed by sequentially stacking a lower electrode material layer 141k, a selection device material layer 143k, a second upper blocking material layer 144k. an intermediate electrode material layer 145k, a heating electrode material layer 147k, a variable resistance material layer 149k, a first upper blocking material layer 146k, and an upper electrode material layer 148k on the first electrode line layer 110L and the first insulating layer 160a. The material or function of each material layer constituting the stack structure 140k are described above, and descriptions thereof are omitted.

Referring to FIG. 16, after forming the stack structure 140k of FIG. 15, a hard mask pattern 180 spaced apart from each other in the first direction (Y direction) and the second direction (X direction) may be formed on the stack structure 140k. The hard mask pattern 180 may be a material pattern for etching a lower etch target layer. The hard mask pattern 180 may be formed into a silicon oxide layer, a silicon nitride layer, a polysilicon layer, or other dielectric layer. In an implementation, the hard mask pattern 180 may include a polysilicon layer 183 and a silicon oxide layer 181.

The hard mask pattern 180 may be formed in an island form spaced apart from each other in the first direction (Y direction) and the second direction (X direction). The hard mask pattern 180 may be patterned by using a photo-resist (PR) pattern formed on a hard mask layer using a photolithography process.

The hard mask pattern 180 may have a very fine pitch of about several tens of nanometers or less. Accordingly, the hard mask pattern 180 may be formed through a process such as double patterning technology (DPT) or quadruple patterning technology (QPT), rather than directly by using a simple PR pattern.

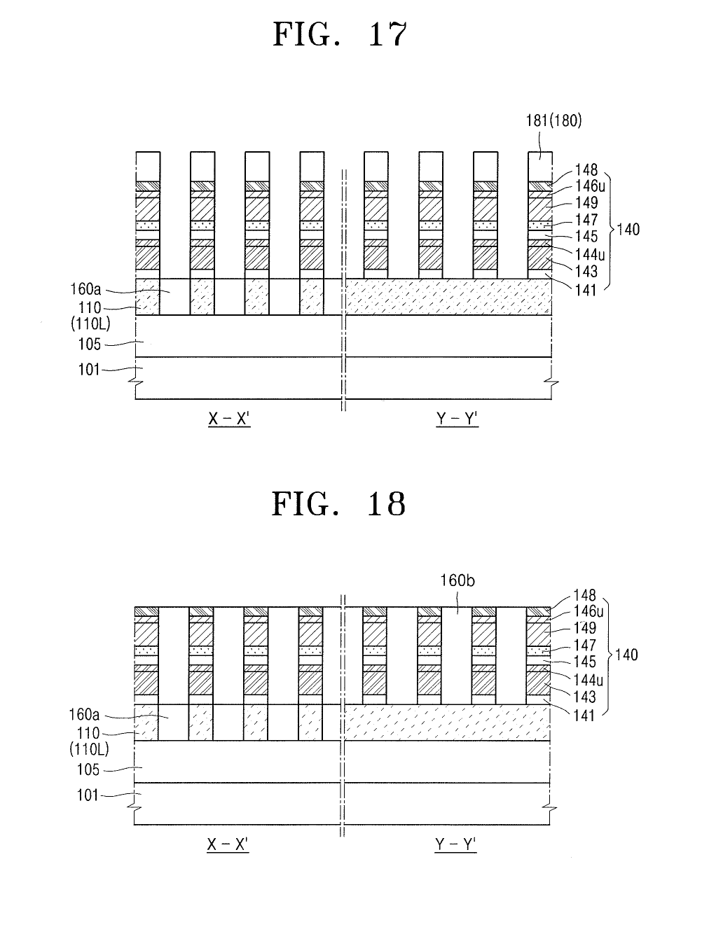

Referring to FIG. 17, the cell structures 140 may be formed by isotropically or anisotropically etching the stack structure 140k by using the hard mask pattern 180. During the formation of the cell structures 140, of the hard mask pattern 180, the polysilicon layer 183 may be etched and removed and the thickness of the silicon oxide layer 181 may be decreased.

The cell structures 140 may be spaced apart from each other in the first direction and the second direction according to the shape of the hard mask pattern 180, and may be electrically connected to the first electrode lines 110 thereunder. The cell structure 140 may be formed by etching the stack structure 140k at one time (e.g., in a single step) by using the hard mask pattern 180, and the first cell structure formed in the first direction (Y direction) shown in the right side of FIG. 17 and the second cell structure formed in the second direction (X direction) shown in the left side of FIG. 17 may have the same shape.

In an implementation, the cell structure 140 may be formed by etching the stack structure 140k at one time by using the hard mask pattern 180, and the cell structure 140 may have various structures according to the shape of the hard mask pattern 180. For example, the cell structure 140 may have a cylindrical column, an elliptical column, or a polygonal column. The shape of the cell structure 140 is described below in detail.

The cell structure 140 may include, e.g., the lower electrode layer 141, the selection device layer 143, the intermediate electrode layer 145, the heating electrode layer 147, the variable resistance layer 149, the upper electrode layer 148, and the blocking layers 144u and 146u. After forming the cell structure 140, a remaining mask pattern may be removed through, e.g., an ashing and strip process, or in a subsequent process.

When the cell structure 140 is formed by isotropically or anisotropically etching the stack structure 140k using the hard mask pattern 180, a second upper blocking material layer 144k and a first upper blocking material layer 146k may help protect the selection device layer 143 and the variable resistance layer 149. For example, the second upper blocking material layer 144k and the first upper blocking material layer 146k may help prevent damage to the selection device layer 143 and the variable resistance layer 149 due to the diffusion of an etch gas for etching the stack structure 140k, e.g., a halogen gas such as fluorine gas (F₂), chlorine gas (Cl₂), or bromine gas (Br₂).

Referring to FIG. 18, the second insulating layer 160b filling between the cell structures 140 may be formed. The second insulating layer 160b may be formed of an oxide or nitride that is the same as or different from the first insulating layer 160a. The second insulating layer 160b may be formed by forming an insulating material layer to have a sufficient thickness so as to completely fill between the cell structures 140 and planarizing the insulating material layer through a chemical mechanical polishing (CMP) process to expose the upper surface of the upper electrode layer 148, thereby forming the second insulating layer 160b.

Thereafter, as illustrated in FIG. 7, a conductive layer for the second electrode line layer 120L may be formed and patterned by etching, thereby forming the second electrode lines 120. The second electrode lines 120 may extend in the second direction (X direction) and may be spaced apart from each other. Next, the third insulating layer 160c extending in the second direction may be formed between the second electrode lines 120.

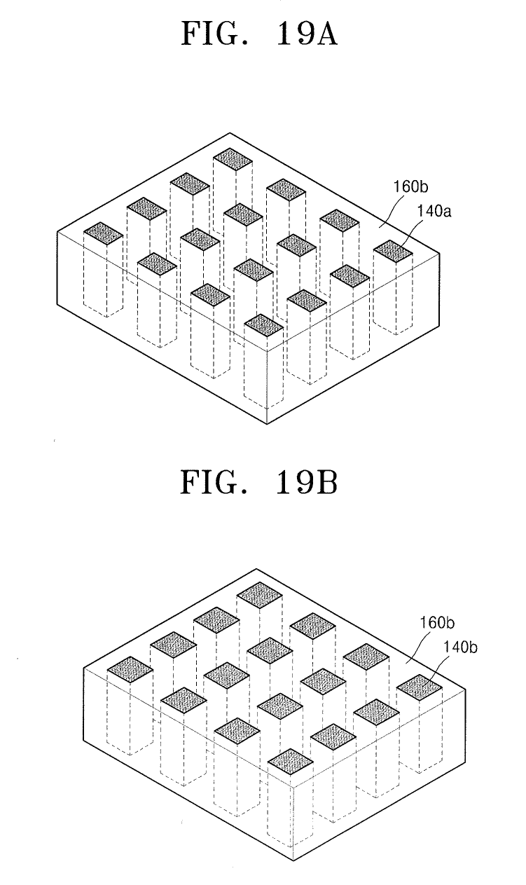

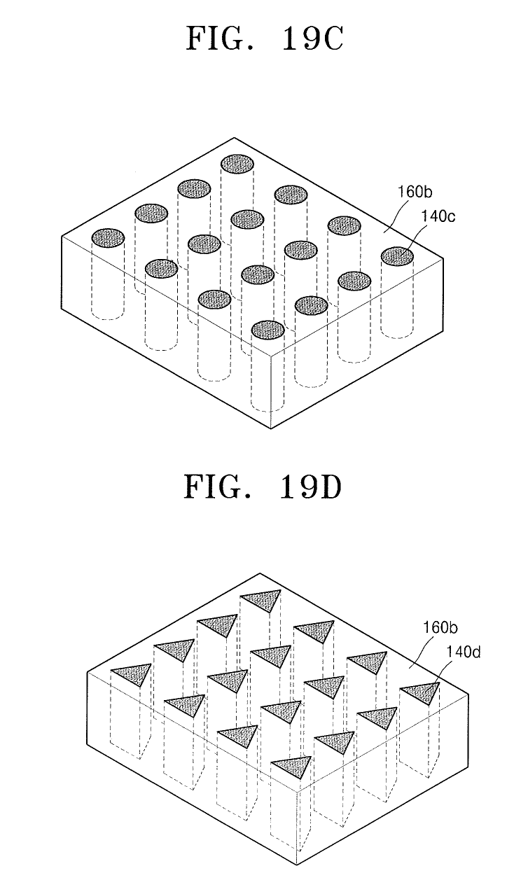

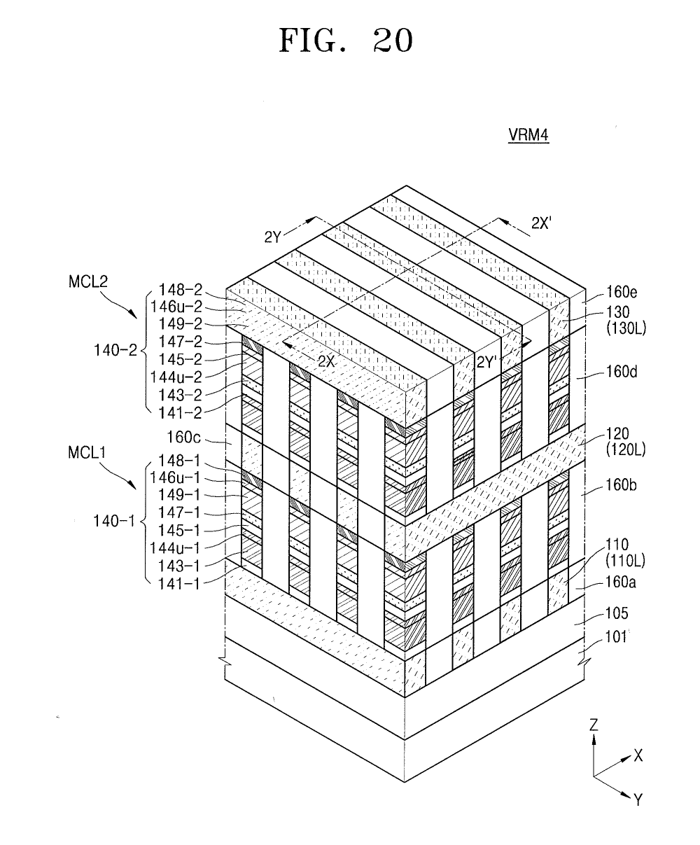

FIGS. 19A to 19D illustrate perspective view of a cell structure of a variable resistance memory device according to an embodiment.

For example, as described above in FIG. 17, the cell structures 140 may be formed by etching the stack structure 140k at one time by using the hard mask pattern 180, and the cell structures 140 may have various structures according to the shape of the hard mask pattern 180.

For example, as illustrated in FIG. 19A, a cell structure 140a may be a rectangular column. As illustrated in FIG. 19B, a cell structure 140b may be a square column. As illustrated in FIG. 19C, a cell structure 140c may be a circular column. As illustrated in FIG. 19D, a cell structure 140d may be a triangular column.

As such, the cell structures 140 of FIG. 17 of the variable resistance memory device may have a shape of, e.g., a circular column, an oval column, or a polygonal column. When the cell structures 140 are formable in a variety of shape, a degree of freedom in design a device may be increased.

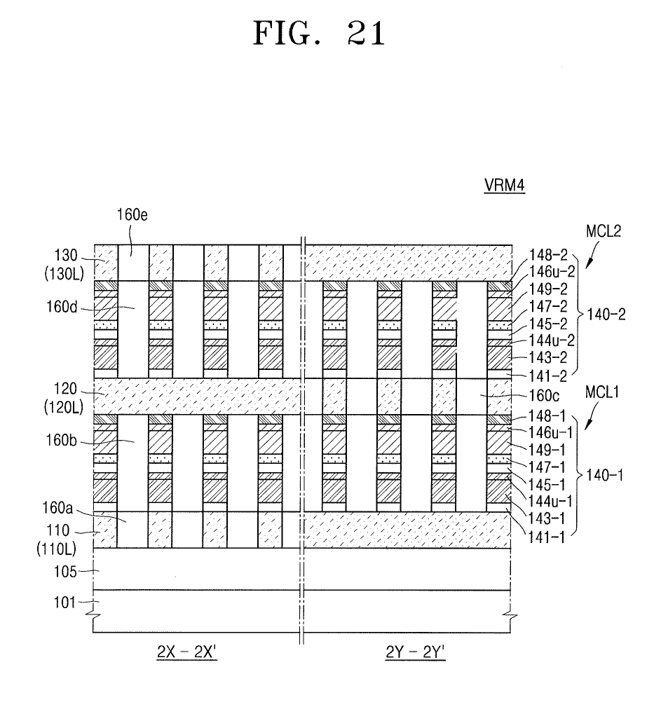

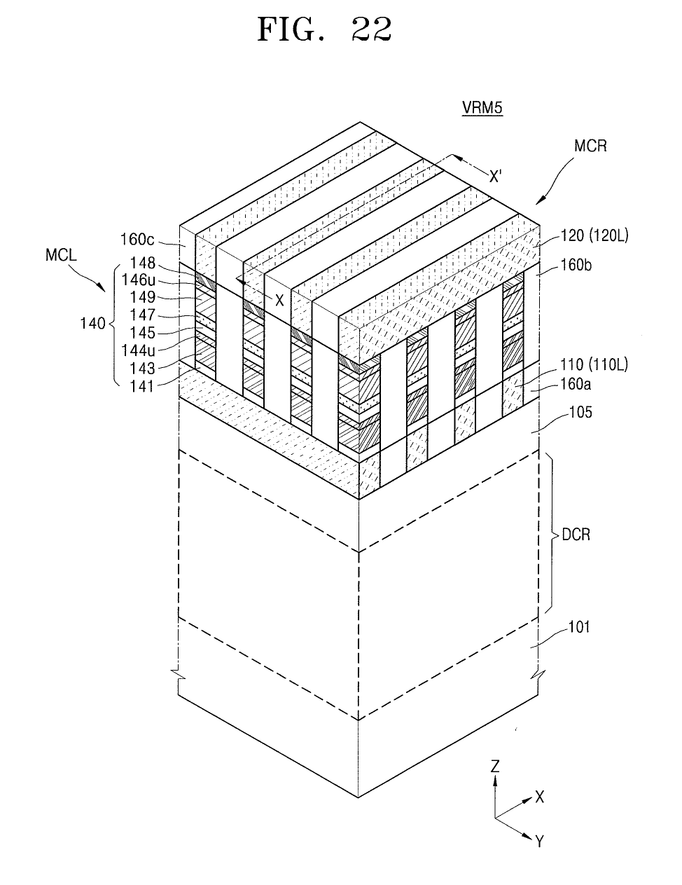

FIG. 20 illustrates a perspective view of a variable resistance memory device VRM4 according to another embodiment. FIG. 21 illustrates a cross-sectional view taken along a line 2X-2X′ and a line 2Y-2Y′ of FIG. 20.

For example, the variable resistance memory device VRM4 may be identical to the variable resistance memory device VRML of FIGS. 6 and 7, except that two memory cell layers MCLs may be stacked. The variable resistance memory device VRM4 may have a double layer structure including two stacked memory cell layers of a first memory cell layer MCL1 and a second memory cell layer MCL2. Accordingly, in the description of FIGS. 20 and 21, the same descriptions as those of FIGS. 6 and 7 may be only briefly presented or omitted.

The first electrode line layer 110L may include a plurality of the first electrode lines 110 extending in the first direction (Y direction) and parallel to each other. The second electrode line layer 120L may be arranged above the first electrode line layer 110L and may include a plurality of the second electrode lines 120 extending in the second direction (X direction) and perpendicular to the first direction, parallel to each other.

A third electrode line layer 130L may be arranged above the second electrode line layer 120L and may include a plurality of third electrode lines 130 extending in the first direction (Y direction) parallel to each other. The third electrode lines 130 may be substantially the same as the first electrode lines 110 in the extending direction or arrangement structure, except for the position in the third direction (Z direction).

In terms of the operation of the variable resistance memory device VRM4, the first electrode lines 110 and the third electrode lines 130 may correspond to the word lines, and the second electrode lines 120 may correspond to the bit lines. In an implementation, the first electrode lines 110 and the third electrode lines 130 may correspond to the bit lines, and the second electrode lines 120 may correspond to the word lines.

When the first electrode lines 110 and the third electrode lines 130 correspond to the word lines, the first electrode lines 110 may correspond to lower word lines and the third electrode lines 130 may correspond to upper word lines. The second electrode lines 120 may be shared by the lower word lines and the upper word lines, and the second electrode lines 120 may correspond to common bit lines.

The first memory cell layer MCL1 may include a plurality of lower cell structures 140-1, e.g., first memory cells, spaced apart from each other in the first direction (Y direction) and the second direction (X direction). The second memory cell layer MCL2 may include a plurality of upper cell structures 140-2, e.g., second memory cells, spaced apart from each other in the first direction and the second direction.

As described above, the first electrode lines 110 and the second electrode lines 120 may cross each other, and the second electrode lines 120 and the third electrode lines 130 may cross each other. The lower cell structures 140-1 (first memory cells) may be arranged at intersections of the first electrode lines 110 and the second electrode lines 120 between the first electrode line layer 110L and the second electrode line layer 120L. The upper cell structures 140-2 (second memory cells) may be arranged at intersections of the second electrode lines 120 and the third electrode lines 130 between the second electrode line layer 120L and the third electrode line layer 130L.

The lower cell structures 140-1 (first memory cells) and the upper cell structures 140-2 (second memory cells) may respectively include, e.g., lower electrode layers 141-1 and 141-2, selection device layers 143-1 and 143-2, intermediate electrode layers 145-1 and 145-2, heating electrode layers 147-1 and 147-2, and variable resistance layers 149-1 and 149-2, upper electrode layers 148-1 and 148-2, and blocking layers 146u-1 and 146u-2.

The first insulating layer 160a may be between the first electrode lines 110, and the second insulating layer 160b may be between the lower cell structures 140-1 of the first memory cell layer MCL1. In an implementation, the third insulating layer 160c may be between the second electrode lines 120, and a fourth insulating layer 160d may be between the upper cell structures 140-2 of the second memory cell layer MCL2. A fifth insulating layer 160e may be between the third electrode lines 130.

In an implementation, the variable resistance memory device VRM4 may have a double layer structure in which two memory cell layers MCL1 and MCL2 are stacked. In an implementation, more memory cell layers may be stacked in the third direction.

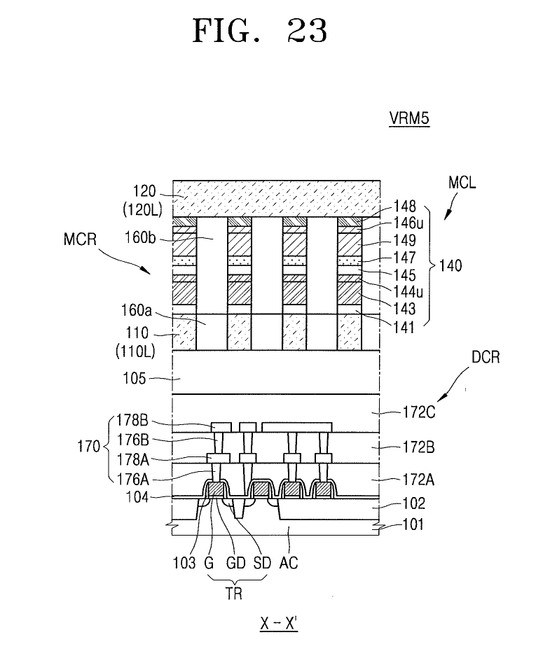

FIG. 22 illustrates a perspective view of a variable resistance memory device VRMS according to an embodiment. FIG. 23 illustrates a cross-sectional view taken along a line X-X′ of FIG. 22.

For example, the variable resistance memory device VRMS according to the present embodiment may be the same as the VRM1, except that a memory cell region MCR may be on or above a driving circuit region (DCR). Accordingly, in the description of FIGS. 22 and 23, the same descriptions as those of FIGS. 6 and 7 may be only briefly presented or omitted.

The variable resistance memory device VRMS may include the driving circuit region DCR on a first level above the substrate 101 and the memory cell region MCR on a second level above the substrate 101. The “level” may signify the height or distance from the substrate 101 in the third direction (vertical direction or the Z direction). The first level may be closer to the substrate 101 than the second level above the substrate 101.

The driving circuit region DCR may be where peripheral circuits or driving circuits to drive memory cells of the memory cell region MCR are arranged, which may correspond to the above-mentioned integrated circuit layer. For example, the peripheral circuits in the driving circuit region DCR may be circuits capable of fast processing input/output data with respect to the memory cell region MCR. For example, the peripheral circuits may be page buffers, latch circuits, cache circuits, column decoders, sense amplifiers, data in/out circuits, or row decoders.

An active region AC for the driving circuits may be defined by a device isolation layer 102 in the substrate 101. A plurality of transistors TR constituting the driving circuit region DCR may be arranged in the active region AC of the substrate 101. Each of the transistors TR may include a gate G, a gate insulating film GD, and a source/drain region SD. Both side walls of the gate G may be covered by an insulating spacer 103, and an etch stop layer 104 may be formed on the gate G and the insulating spacer 103.

The etch stop layer 104 may include an insulating material such as a silicon nitride or a silicon oxynitride. A plurality of the lower interlayer insulating layers 172A, 172B, and 172C may be sequentially stacked on or above the etch stop layer 104. The lower interlayer insulating layers 172A, 172B, and 172C may include a silicon oxide, a silicon oxynitride, or a silicon oxynitride.

The driving circuit region DCR may include a multilevel interconnect structure 170 electrically connected to the transistors TR. The multilevel interconnect structure 170 may be insulated by the lower interlayer insulating layers 172A, 172B, and 172C. The multilevel interconnect structure 170 may include a first contact 176A, a first interconnect layer 178A, a second contact 176B, and a second interconnect layer 178B, which are sequentially stacked on or above the substrate 101 and electrically connected to one another.

In an implementation, the first interconnect layer 178A and the second interconnect layer 178B may be formed of, e.g., metal, a conductive metal nitride, a metal silicide, or a combination thereof. For example, the first interconnect layer 178A and the second interconnect layer 178E may include a conductive material such as tungsten. molybdenum, titanium, cobalt, tantalum, nickel, tungsten silicide, titanium silicide, cobalt silicide, tantalum silicide, or nickel silicide.

In an implementation, the multilevel interconnect structure 170 may have a double layer interconnect structure including the first interconnect layer 178A and the second interconnect layer 178B. In an implementation, the multilevel interconnect structure 170 may have a multilevel interconnect structure of three or more layers according to the layout of the driving circuit region DCR or the type and array of the gate G.

The interlayer insulating layer 105 may be formed on or above the lower interlayer insulating layers 172A, 172B, and 172C. The memory cell region MCR may be arranged on or above the interlayer insulating layer 105. The interlayer insulating layer 105 and the memory cell region MCR are the same as those described above. For example, the memory cell region MCR may include the first electrode line layer 110L, the memory cell layer MCL, and the second electrode line layer 120L. In an implementation, an interconnect structure connected between the memory cell region MCR and the driving circuit region DCR may be arranged by passing through the interlayer insulating layer 105. In the present embodiment, as the memory cell region MCR is arranged above the driving circuit region DCR, a degree of integration of memory devices may be greatly improved.

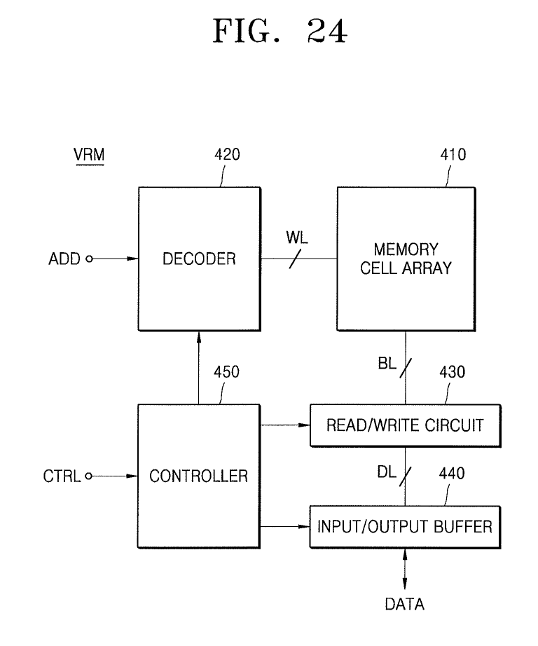

FIG. 24 illustrates a block diagram of a configuration of a variable resistance memory device VRM according to an embodiment.

For example, the variable resistance memory device VRM according to an embodiment may include a memory cell array 410, a decoder 420, a read/write circuit 430, an input/output buffer 440, and a controller 450. Since the memory cell array 410 is described above, a description thereof is omitted.

A plurality of memory cells in the memory cell array 410 may be connected to the decoder 420 via the word line WL, and connected to the read/write circuit 430 via the bit line BL. The decoder 420 receives an external address ADD and decodes a row address and a column address to access in the memory cell array 410 under the control of the controller 450 operated according to a control signal CTRL.

The read/write circuit 430 receives data DATA from the input/output buffer 440 and a data line DL, and writes the data DATA to a selected memory cell of the memory cell array 410 under the control of the controller 450 or provides the input/output buffer 440 with the data DATA read from a selected memory cell of the memory cell array 410 under the control of the controller 450.

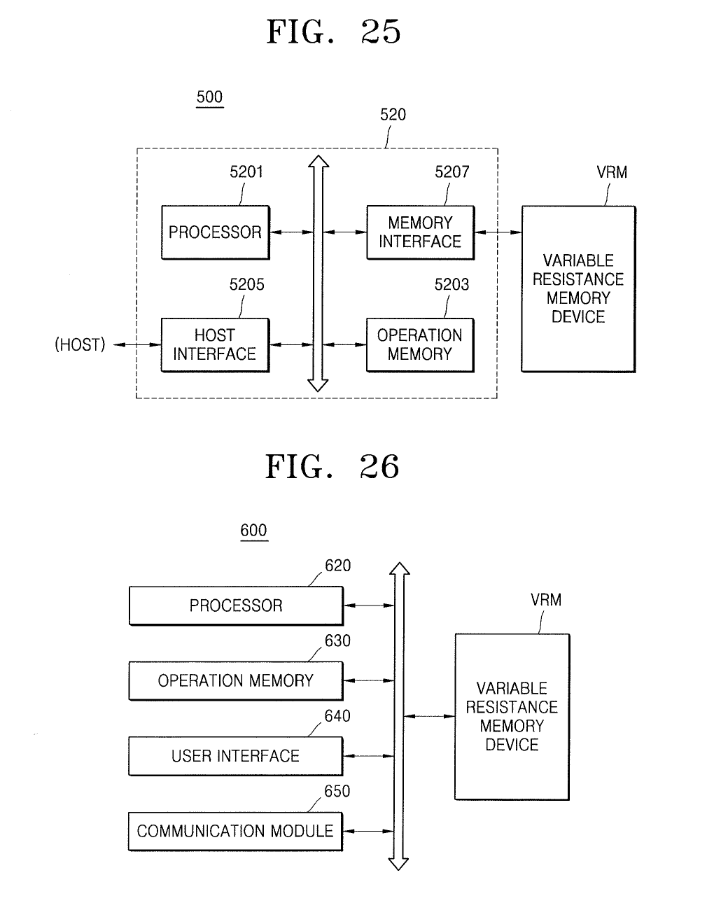

FIG. 25 illustrates a block diagram of a configuration of a data processing system 500 including the variable resistance memory device VRM, according to an embodiment.

For example, the data processing system 500 may include a memory controller 520 connected between a host and the variable resistance memory device VRM. The memory controller 520 may be configured to access the variable resistance memory device VRM in response to a request by the host. The memory controller 520 may include a processor 5201, an operation memory 5203, a host interface 5205, and a memory interface 5207.

The processor 5201 may control an overall operation of the memory controller 520, and the operation memory 5203 may store applications, data, or control signals needed for the operation of the memory controller 520. The host interface 5205 performs protocol conversion for exchanging data/control signals between the host and the memory controller 520. The memory interface 5207 performs protocol conversion for exchanging data/control signals between the memory controller 520 and the variable resistance memory device VRM. Since the variable resistance memory device VRM is described above, a description thereof is omitted. The data processing system 500 may be a memory card, but the present disclosure is not limited thereto.

FIG. 26 illustrates a block diagram of a configuration of a data processing system 600 including the variable resistance memory device VRM, according to another embodiment.

For example, the data processing system 600 may include the variable resistance memory device VRM, a processor 620, an operation memory 630, and a user interface 640, and may further include a communication module 650, as desired. The processor 620 may be a central processing unit.

The operation memory 630 may store applied programs, data, or control signals needed for the operation of the data processing system 600. The user interface 640 may provide an environment for a user to access the data processing system 600, and provide the user with a data processing process or a process result of the data processing system 600.

The variable resistance memory device VRM is the same as that described in the above. The data processing system may be used as a disk device, an internal/external memory card of portable electronic devices, an image processor, or other applied chipsets.

The embodiments may provide a variable resistance memory device that may help reduce and/or prevent property degradation of a cell structure.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features. characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

1. A variable resistance memory device, comprising:
a first electrode line;
a cell structure including a variable resistance layer on the first electrode line and a first blocking layer protecting the variable resistance layer; and
a second electrode line on the cell structure,
wherein:
the first blocking layer is on at least one of an upper surface, a lower surface, and the upper and lower surfaces of the variable resistance layer, and
the first blocking layer includes a metal layer or a carbon-containing conductive layer.

2. The variable resistance memory device as claimed in claim 1, wherein the cell structure further includes a selection device layer.

3. (canceled)

4. The variable resistance memory device as claimed in claim 2, wherein:
the cell structure further includes a second blocking layer on at least one of an upper surface, a lower surface, and the upper and lower surfaces of the selection device layer, and
the second blocking layer includes a metal layer or a carbon-containing conductive layer.

5. The variable resistance memory device as claimed in claim 4, wherein the cell structure further includes an intermediate electrode layer on the selection device layer.

6. The variable resistance memory device as claimed in claim 5, wherein the second blocking layer is on a lower surface of the intermediate electrode layer.

7. The variable resistance memory device as claimed in claim 5, wherein the cell structure is a structure in which the selection device layer, the intermediate electrode layer, and the variable resistance layer are sequentially stacked on the first electrode line.

8. The variable resistance memory device as claimed in claim 7, wherein:
the cell structure further includes a lower electrode layer under the selection device layer and an upper electrode layer above the variable resistance layer, and
the first blocking layer or the second blocking layer is on at least one of an upper surface of the lower electrode layer or a lower surface of the upper electrode layer.

9. The variable resistance memory device as claimed in claim 8, wherein:
the cell structure further includes a heating electrode layer on the intermediate electrode layer, and
the first blocking layer is on the heating electrode layer.

10. (canceled)

11. (canceled)

12. A variable resistance memory device, comprising:
a plurality of first electrode lines extending in a first direction and arranged in parallel and spaced apart from each other;
a plurality of second electrode lines extending in a second direction perpendicular to the first direction, above the plurality of first electrode lines, and arranged in parallel and spaced apart from each other; and
a plurality of memory cells at intersections of the plurality of first electrode lines and the plurality of second electrode lines and spaced apart from each other,
wherein:
each of the plurality of memory cells includes a cell structure that is electrically connected to one of first electrode lines and one of second electrode lines, and includes a selection device layer, an intermediate electrode layer, a variable resistance layer, and a blocking layer,
the blocking layer is on at least one of an upper surface, a lower surface, and the upper and lower surfaces of the selection device layer or the variable resistance layer, and
the blocking layer includes a metal layer or a carbon-containing conductive layer.

13. The variable resistance memory device as claimed in claim 12, wherein:
the cell structure includes a first cell structure arranged in the first direction and a second cell structure arranged in the second direction, and
the first cell structure has a same shape and a same structure as a shape and a structure of the second cell structure.

14. (canceled)

15. The variable resistance memory device as claimed in claim 12, wherein:
the plurality of first electrode lines are word lines and the plurality of second electrode lines are bit lines, or
the plurality of first electrode lines are bit lines and the plurality of second electrode lines are word lines.

16. The variable resistance memory device as claimed in claim 12, wherein:
the cell structure is a structure in which the selection device layer, the intermediate electrode layer, and the variable resistance layer are sequentially stacked on the plurality of first electrode lines, and
the blocking layer is on a lower surface of the intermediate electrode layer.

17. The variable resistance memory device as claimed in claim 12, wherein:
the cell structure further includes a lower electrode layer under the selection device layer, and
the blocking layer is on an upper surface of the lower electrode layer.

18. The variable resistance memory device as claimed in claim 12, wherein:
the cell structure further includes an upper electrode layer above the variable resistance layer, and
the blocking layer is on a lower surface of the upper electrode layer.

19. The variable resistance memory device as claimed in claim 12, wherein:
the cell structure further includes a heating electrode layer above the intermediate electrode layer, and
the blocking layer is formed above the heating electrode layer.

20.-26. (canceled)

27. A variable resistance memory device, comprising:
a first electrode line;
a second electrode line; and
a cell structure between the first electrode line and the second electrode line, the cell structure including a variable resistance layer on the first electrode line and a first blocking layer protecting the variable resistance layer,
wherein:
the first blocking layer directly contacts at least one surface of the variable resistance layer, and
the first blocking layer includes a metal layer or a carbon-containing conductive layer.

28. The variable resistance memory device as claimed in claim 27, wherein the cell structure further includes a selection device layer.

29. The variable resistance memory device as claimed in claim 28, wherein:
the cell structure further includes a second blocking layer directly contacting at least one surface of the selection device layer, and
the second blocking layer includes a metal layer or a carbon-containing conductive layer.

30. The variable resistance memory device as claimed in claim 28, wherein:
the cell structure further includes an intermediate electrode layer on the selection device layer, and
the cell structure is a structure in which the selection device layer, the intermediate electrode layer, and the variable resistance layer are sequentially stacked on the first electrode line.

31. The variable resistance memory device as claimed in claim 27, wherein the variable resistance layer includes a phase change layer or a resistance change layer.
